(19) United States
(12) Patent Application Publication
(10) Pub. No.: US 2009/0194774 A1
(43) Pub. Date: Aug. 6, 2009

(54) Light source module with wavelength converting structure and the method of forming the same

(75) Inventors: Hsin-Tao Huang, Zhubei City (TW); Chun-Chung Hsiao, Caotun Township (TW)

Correspondence Address: BACON & THOMAS, PLLC, 625 SLATERS LANE, FOURTH FLOOR, ALEXANDRIA, VA, 22314-1176, US

(73) Assignee: KISMART CORPORATION, Taipei City (TW)

(21) Appl. No.: 12/068,142

(22) Filed: Feb. 4, 2008

(51) Int. Cl. H01L 33/00

(52) U.S. Cl. 257/88; 257/E33.001

(57) ABSTRACT

A light source package module with a wavelength converting structure is provided. The light source package module comprises a frame having a substrate and sidewalls formed on the substrate. A plurality of LED dice is disposed on the substrate, and there is a space between each of the LED dice. A wavelength converting structure is disposed on above the plurality of LED dice and the sidewalls. The light source package can provide a flat light source with a large emitting area can be made in simply as well. Additionally, the present invention further relates to the application of a backlight module.

### BACKGROUND OF THE INVENTION

1. Field of the Invention

The invention relates to a light source module, more particularly to a light source with a shared wavelength converting structure and the method of forming the same.

2. Descriptions of the Related Art

The trend for light sources used in displays has become increasingly flat with large emitting areas. The flat light sources with large emitting areas are very important for backlight modules in large-sized flat panel liquid crystal displays. For various conventional light sources, the means currently used to provide visible light through energy/wavelength conversion includes cold cathode fluorescent lamps (CCFL), external electrode fluorescent lamps (EEFL), light emitting diodes (LED), carbon nanotubes (CNT), flat fluorescent lamps (FFL), and organic light emitting displays (OLED).

In order to providing large scale illumination, some drawbacks are generated with the increase of the dimension, “Mura effect” is one of the issues. Mura effect is a phenomenon about all kinds of uneven or non-uniform brightness. Especially, when the large-scale illumination is employed with a plurality of lighting units, the mura effect is more serious than ever if the number of lighting units is insufficient therefore the distance between lighting units is too large, it causes the illumination is non-uniform.

The existing sources of visible light either lack the maturity in terms of producing a large-scale light source due to their innate limitations in production, both failing to convert light in a large area using simple and inexpensive means.

One candidate for high efficient illumination is LED which is not only lower power consumption, but also fulfill the green function requirement. However, all of the current LED is assembly with only one die with therein. It is unlikely to be employed for large scale illumination. Therefore, the present invention is to provide a light source with multiple die. However, the inventor discovers that the mura effect will be generated provided only with multiple LED die. In view of the above, what is required is multiple LED die assembly with a shared mura elimination structure.

### SUMMARY OF THE INVENTION

One objective of the present invention is to provide a light source module comprising: an enclosure having a substrate formed therein; a plurality of LED (light emitting diode) dice disposed on the substrate; and a shared wavelength converting structure disposed on the enclosure to reduce mura effect and convert a first wavelength of the light from the plurality of LED dice into a second wavelength.

Another objective of the present invention is to provide a method for producing a light source module, the method comprises step of providing an enclosure having a substrate formed therein; the next step is to dispose a plurality of LED (light emitting diode) dice on the substrate; and a shared wavelength converting structure is disposed on the enclosure and over the plurality of LED dice to reduce mura effect and convert a first wavelength of the light from the plurality of LED dice into a second wavelength.

In combination with a light source, the shared wavelength converting structure may have a transparent plate with a wavelength converting layer thereon to improve the uniformity of the light emission and reduce the mura effect. The present invention can improve the uniformity of brightness of a flat light source with multiple lighting elements and provide a flat source of visible light with a large area. Further, the present invention also simplifies the manufacture process for forming phosphor powders on the plate. The light source of the present invention can further be applied in a backlight module for a display panel with a larger scale by simple means.

After reviewing the embodiments described below, persons having ordinary skill in the art can easily appreciate the basic spirit and other inventive objective of the subject invention and the technical means and preferred embodiments implemented for the subject invention.

### BRIEF DESCRIPTION OF THE DRAWINGS

FIG. 1A depicts an illustrative view of an embodiment of a wavelength converting structure in accordance with the subject invention.

FIG. 1B depicts an illustrative view of another embodiment of the wavelength converting structure in accordance with the subject invention, wherein a substrate contained therein is a composite layer.

FIG. 1C depicts an illustrative view of yet another embodiment of the wavelength converting structure in accordance with the subject invention, wherein a substrate contained therein is an optical enhancement layer.

FIG. 2 depicts an embodiment of a light-emitting module comprising a UV-blocking layer.

FIG. 3A depicts an exploded view of an embodiment illustrating a light source module with a shared wavelength converting structure according the present invention.

FIG. 3B depicts a sectional view of the light source module shown in FIG. 3A.

FIG. 4 depicts a sectional view illustrating an application for a backlight module.

### DESCRIPTION OF THE PREFERRED EMBODIMENT

Some sample embodiments of the invention will now be described in greater detail. Nevertheless, it should be recognized that the present invention can be practiced in a wide range of other embodiments besides those explicitly described, and the scope of the present invention is expressly not limited except as specified in the accompanying claims. Then, the components of the different elements are not shown to scale. Some dimensions of the related components are exaggerated and meaningless portions are not drawn to provide clearer description and comprehension of the present invention.

The present invention is to dispose the shared wavelength converting structure over the plurality of LED dice in order to improve the uniformity of the light emission and reduce the mura effect resulted from light source consisting of multiple lighting elements, further, since the phosphor powers are coated on the shared plate instead of over the individual die (multiple lighting elements), respectively, therefore, the present invention simplify the manufacture process, consequently, the cost is reduced. The shared wavelength converting structure of the present invention can improve the uniformity of the light emission from the flat light source with multiple lighting elements and optionally provide the desired light emitting area. Therefore, since the shared wavelength converting layer is separate from the light source in the present invention, the above problems can be effectively eliminated.

The present invention discloses a structure with phosphor powder or other material to improve the uniformity of the light emission and reduce the mura effect. The structure could be employed and plays the roles of wavelength converting under the multi-LED scheme. These embodiments will be illustrated as follows.

In this disclosure, the term “UV_{C}” refers to the ultraviolet rays with a wavelength of no more than 280 nm. It is preferred for the wavelength to fall between 200 nm to 280 nm, and particularly from 250 nm to 260 nm. It is best to have a wavelength of 253.7 nm. The term “UV_{B}” refers to the light rays with a wavelength ranging from 280 nm to 320 nm, while the term “UV_{A}” refers to the light rays with a wavelength ranging from 320 nm to 400 nm. The phrase “the material which is excitable by ultraviolet ray (or by UV_{C}, UV_{A} or UV_{B})” refers to a material that can absorb ultraviolet rays (or UV_{C}, UV_{A} or UV_{B}) and emit visible light when irradiated by ultraviolet rays (or by UV_{C}, UV_{A} or UV_{B}).

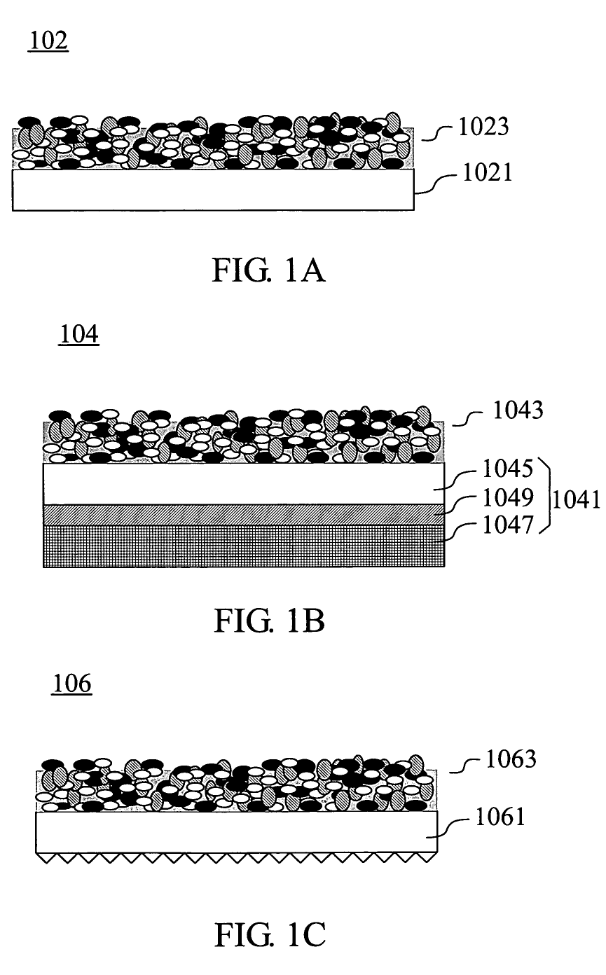

In order to convert wavelength and improve the uniformity of the light emission to reduce the mura effect, one of embodiments according to the present invention is to provide a shared wavelength converting structure, an embodiment of which is illustrated in FIG. 1A illustrates one embodiments of the present invention, where [symbol] , and [symbol] respectively denote the phosphor powders of different colors. Preferably, the material can include photoluminescent layer, fluorescent color-conversion-media, organic complex material, luminescent pigments, quantum dots-based material, quantum wire-based material and quantum well-based material and combinations thereof. The shared wavelength converting structure 102 comprises a transparent plate 1021 and wavelength converting layer 1023. The layer 1023 is disposed on the transparent plate 1021, and comprises a phosphor powder which is excitable by UV_{C} and an anti-UV_{C} adhesive. The thickness of the shared wavelength converting layer 1023 is 2 to 10 times the average particle size of the phosphor powder, and the amount of the phosphor powder in the wavelength converting layer 1023 conforms to at least one of the following requirements:

(i) the phosphor powder is 30% to 85% by volume of the shared wavelength converting layer based on the total volume of the phosphor powder and the adhesive; and

(ii) the weight ratio of the phosphor powder to the adhesive ranges from 1:1 to 20:1.

Any appropriate phosphor powder excitable by UV_{C} may be adopted in the shared wavelength converting layer. For example (but not limited thereto), the phosphor powder may be selected from a group consisting of europium doped yttrium oxide, terbium doped cerium lanthanum phosphate, europium doped barium magnesium aluminum oxide, and combinations thereof. Appropriate products available directly in the market can also be used as the phosphor powder of the wavelength converting layer.

In the wavelength converting layer, the employed adhesive can bond the phosphor powder to form a wavelength converting layer, and it is usually selected from macromolecular adhesives. However, when the layer is employed in combination with UV_{C}, anti-UV_{C} adhesives are preferred in the scheme to prevent the degradation of the adhesive itself caused by the exciting process.

A transparent thin sheet may also be used as the transparent plate of the above shared wavelength converting structure. The transparent plate can be a flexible film, especially a flexible film made of a polymer to facilitate the conventional roll-to-roll coating approach for mass production. The flexible film is preferably transparent, if not, highly transparent.

For example (but not limited thereto), the transparent plate can be a thin sheet made of glass, quartz, poly(methyl methacrylate) (PMMA), polystyrene (PS), methyl methacrylate-co-styrene (MS), or polycarbonate (PC). Alternatively, a light transmissive fiber fabric (typically made of glass) may be used as the transparent plate. Still alternatively, a composite layer composed of two or more aforesaid films and/or thin sheets may be adopted as the transparent plate, in which case a pressure sensitive polymer adhesive may be utilized to bond the individual layers.

The shared wavelength converting structure may be applied in a light-emitting module. In this case, an optical enhancement structure such as a prismatic or a particulate structure can be formed on one side of the transparent plate opposite to the shared wavelength converting layer to further enhance the optical effect. Optionally, to enhance the brightness or the polarizing effect, the shared wavelength converting structure may further comprise any appropriate optical elements, for example, an optical film or sheet such as a diffusion plate, a diffusion film, a brightness enhancement film (BEF), a dual brightness enhancement film (DBEF), a prism plate, a lenticular film, a polarizer, and combinations thereof.

Another embodiment of the shared wavelength converting structure is illustrated in FIGS. 1B and 1C, where [symbol] and [symbol] respectively denote the phosphor powders of different colors. In FIG. 1B, the shared wavelength converting structure 104 comprises a transparent plate 1041 and a wavelength converting layer 1043 on the transparent plate 1041. The transparent plate 1041 is a composite layer, which is composed of a transparent film 1045 (e.g., a PET film) adhered to a transparent sheet 1047 (e.g., a PMMA, MS or PC sheet) via a pressure sensitive polymer adhesive 1049. The shared wavelength converting structure 106 illustrated in FIG. 1C comprises a transparent plate 1061 and a wavelength converting layer 1063 on the transparent plate 1061. Here, the transparent plate 1061 is an optical enhancement structure with a prismatic structure or a diffusion structure disposed on one side. Optionally, a protection film such as a PET film may be disposed on the transparent plate for protection.

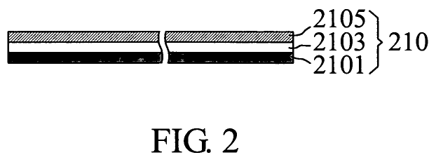

To eliminate the adverse influence of the small amount of UV_{A} light and/or UV_{B} light, a UV-blocking coating may be further included in the shared wavelength converting structure of the light-emitting module of the light-emitting module, in addition to the phosphor powders that can absorb UV_{C}, UV_{A} and UV_{B}, to mitigate any possible UV leakage. An illustration of the embodiment of a light-emitting module with such a UV-blocking coating is depicted in FIG. 2.

FIG. 2 depicts one embodiment of the shared wavelength converting structure 210, which comprises from bottom to top a wavelength converting layer 2101, a transparent plate 2103 and a W-blocking coating 2105. That is, the shared wavelength converting layer 2101 and the UV-blocking coating 2105 are respectively disposed on either side of the transparent plate 2103. Alternatively, the UV-blocking coating 2105 can be optionally disposed on the same side of the transparent plate 2103 as the wavelength converting layer 2101.

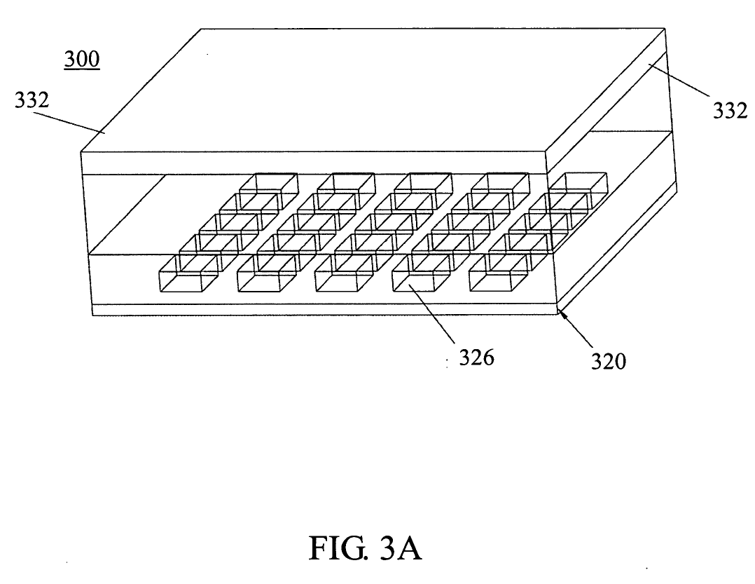

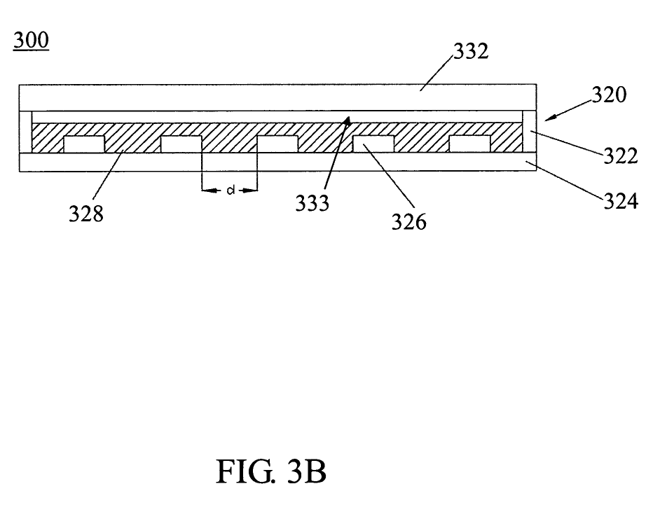

The preferred embodiment is employed for light illumination or the like. As illustrated in FIGS. 3A and 3B, multi-LED die assembly is provided. The present invention discloses a light source package module 300 with a shared wavelength converting structure to reduce the mura effect and improve the uniformity of the light emission, as shown in FIG. 3A in an exploded view. The light source module 300 includes an enclosure 320, a plurality of LED (light emitting diode) dice 326 and a shared wavelength converting structure 332. Preferably, a reflector sheet is formed inside said enclosure 320 to reflect the light from the plurality of LED dice 326. The reflector sheet may include a phosphor layer coated thereon. Referring to FIG. 3B, it is a sectional view of the light source module 300 in FIG. 3A, the light source module includes an enclosure 320 having a substrate 324. A plurality of LED dice 326 is disposed over the substrate in an array configuration. A filling material 328 is filled between dice. Preferably, the filling material 328 includes silicone.

The shared wavelength converting structure 332 is adhered on the sidewalls of the enclosure and over the LED dice 326. The shared wavelength converting structure 332 is used to improve the uniformity of the light emission and reduce or eliminates the mura effect generated by the multi-die in array configuration.

Any appropriate material may be adopted in the shared wavelength converting structure. Preferably, the material of the shared wavelength converting structure 332 includes phosphor, photoluminescent layer, fluorescent color-conversion-media, organic complex material, luminescent pigments, quantum dots-based material, quantum wire-based material and quantum well-based material and combinations thereof.

The shared wavelength converting structure 332 can be excited by UVc. A visible or white light may be emitted by exciting the shared wavelength converting layer through UVc. Preferably, the material of the shared wavelength converting structure 332 can be excited by UVc with a wavelength of about 253.7 nm, or a wavelength ranging from about 200 nm to about 280 nm or from about 250 nm to about 260 nm.

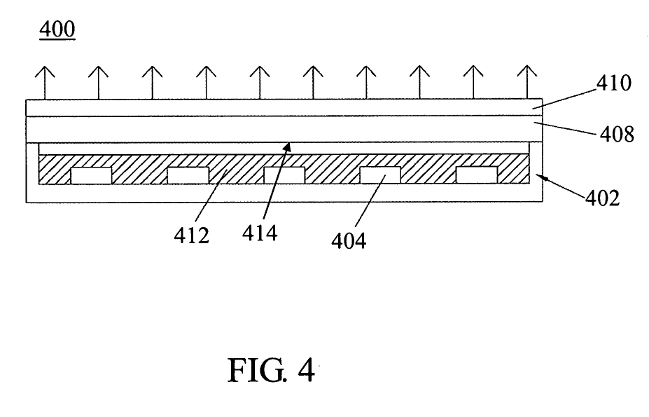

The light source of the present invention can be applied for a backlight module application as shown in FIG. 4 in a sectional view. The backlight module 400 includes a frame 402, a plurality of LED (light emitting diode) dice 404, and a shared wavelength converting structure 408. A filling material 412 is filled in the cavity 414 of the frame 402. Preferably, the filling material 412 includes silicone.

The shared wavelength converting structure 408 is adhered on the sidewalls and above the LED dice 404 thereby forming the cavity 414. As a result, the ultraviolet rays, particularly those with the UV_{C} spectrum band, are converted into a visible light through the shared wavelength converting structure.408.

Furthermore, the backlight module 400 may include an optical element 410 formed on the shared wavelength converting structure.408. Optionally, to enhance the brightness or the polarizing effect, the backlight module 400 may further add any appropriate optical elements, for example, an optical film or sheet such as a diffusion plate, a diffusion film, a brightness enhancement film (BEF), a dual brightness enhancement film (DBEF), a prism plate, a lenticular film, a polarizer, and combinations thereof.

Optionally, the backlight module 400 may further include a UV- blocking layer formed on the shared wavelength converting structure.408. The UV-blocking layer can be made of any material that can block UV light, preferably, a UV-blocking material, a UV-stabilizing material, a UV absorptive material, a UV reflective material, or combinations thereof.

The present invention also discloses a method for producing a light source module with a wavelength converting structure. First, an enclosure with a substrate and sidewall formed on the substrate is provided. Alternatively, a reflector sheet may be formed inside said enclosure and the reflector sheet includes a phosphor layer coated thereon. Later, the step of disposing a plurality of LED dice on the substrate is performed in an array configuration.

Sequentially, a filling material is filling into the opening of the enclosure, preferably, the filling material includes silicone. Afterward, the step of disposing the shared wavelength converting structure on the enclosure is performed. Preferably, the shared wavelength converting structure with can be excited by UVc, which an anti-UVc adhesive and an organic solvent. Any appropriate organic solvent may be used as a carrier for the material and the adhesive of the shared wavelength converting structure. The material and the adhesive of the shared wavelength converting structure can be blended into the solvent prior to or during the coating process to form a desired slurry, which is then coated onto the surface of the transparent plate to form the shared wavelength converting structure. Subsequently, the solvent is removed through a drying process to eventually form the desired wavelength converting layer on the transparent plate. The material of the shared wavelength converting structure may include phosphor, photoluminescent layer, fluorescent color-conversion-media, organic complex material, luminescent pigments, quantum dots-based material, quantum wire-based material and quantum well-based material and combinations thereof. The shared wavelength converting structure can be excited by UVc with a wavelength of about 253.7 nm, or a wavelength ranging from about 200 nm to about 280 nm or from about 250 nm to about 260 nm. A visible or white light may be emitted by exciting the slurry through UVc.

The step of disposing the transparent plate with the wavelength converting structure over the plurality of LED dice and the sidewalls is performed. Optionally, other components can be added to the shared wavelength converting structure to prolong the service life of the wavelength converting structure. The process of the present invention may include forming a UV-blocking layer on the transparent plate. Preferably, the UV-blocking layer comprises a component selected from a group consisting of a stabilizer, an absorbent, a blocker, and combinations thereof.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A light source module, comprising:
an enclosure;
a plurality of LED (light emitting diode) dice disposed in said enclosure; and
a shared wavelength converting structure disposed on said enclosure to reduce mura effect and convert a first wavelength of the light from said plurality of LED dice into a second wavelength.

2. The module of claim 1, wherein a filling material is filled in the cavity between said enclosure and said wavelength converting structure.

3. The module of claim 2, wherein said filling material includes silicone.

4. The module of claim 1, wherein said wavelength converting structure includes an anti-UVc adhesive.

5. The module of claim 1, wherein said wavelength converting structure is excitable by UVc.

6. The module of claim 1, wherein the material of said wavelength converting structure includes phosphor, photoluminescent layer, fluorescent color-conversion-media, organic complex material, luminescent pigments, quantum dots-based material, quantum wire-based material and quantum well-based material and combinations thereof.

7. The module of claim 1, further comprising an optical element formed on said wavelength converting structure, which is selected from a group consisting of a diffusion plate, a diffusion film, a brightness enhancement film, a prism plate, a dual brightness enhancement film, a polarizer, a lenticular film, and/or the combinations thereof.

8. The module of claim 1, further comprising a UV-blocking layer formed on said wavelength converting structure, wherein said UV-blocking layer includes a component selected from a group consisting of a stabilizer, an absorbent, a blocker, and the combinations thereof.

9. The module of claim 1, wherein said wavelength converting structure includes a transparent plate and a phosphor layer.

10. The module of claim 1, wherein said light source module is employed for a backlight module.

11. The module of claim 1, further comprising a reflector sheet formed inside said enclosure.

12. The module of claim 11, wherein said reflector sheet includes a phosphor layer coated thereon.

13. A method for producing a light source module, comprising:
providing an enclosure;
disposing a plurality of LED (light emitting diode) dice in said exclosure; and
disposing a shared wavelength converting structure on said enclosure and over said plurality of LED dice to reduce mura effect and convert a first wavelength of the light from said plurality of LED dice into a second wavelength.

14. The method of claim 13, further comprising filling a filling material into the opening of said enclosure.

15. The module of claim 13, wherein said filling material includes silicone.

16. The method of claim 13, wherein said wavelength converting structure includes an anti-UVc adhesive and an organic solvent.

17. The method of claim 13, wherein said wavelength converting structure is excitable by UVc.

18. The method of claim 13, wherein the material of said wavelength converting structure includes phosphor, photoluminescent layer, fluorescent color-conversion-media, organic complex material, luminescent pigments, quantum dots-based material, quantum wire-based material and quantum well-based material and combinations thereof.

19. The method of claim 13, further comprising forming an optical element on said wavelength converting structure, wherein said optical element is selected from a group consisting of a diffusion plate, a diffusion film, a brightness enhancement film, a prism plate, a dual brightness enhancement film, a polarizer, a lenticular film, and combinations thereof.

20. The method of claim 13, further comprising forming a UV-blocking layer on said wavelength converting structure, wherein the UV-blocking layer includes a component selected from a group consisting of a stabilizer, an absorbent, a blocker, and combinations thereof.

21. The module of claim 13, wherein said light source module is employed for a backlight module.

22. The module of claim 13, further comprising a reflector sheet formed on the sidewall inside said enclosure.

23. The module of claim 22, wherein said reflector sheet includes a phosphor layer coated thereon.
